(19) United States
(12) Patent Application Publication
(10) Pub. No.: US 2025/0218719 A1
(43) Pub. Date: Jul. 3, 2025

(54) MULTI-BEAM PARTICLE MICROSCOPE WITH IMPROVED BEAM TUBE

(71) Applicant: Carl Zeiss MultiSEM GmbH, Oberkochen (DE)

(72) Inventors: Michael Kelp, Gerstetten (DE); Maxim Mikirtychiyants, Heidenheim (DE); Sandra Vogel, Ulm (DE); Ralf Lenke, Lauchheim (DE); Ingo Mueller, Aalen (DE); Dieter Schumacher, Heidenheim (DE); Joerg Jacobi, Heidenheim (DE)

(21) Appl. No.: 19/085,479

(22) Filed: Mar. 20, 2025

Related U.S. Application Data
(63) Continuation of application No. PCT/EP2023/025402, filed on Sep. 21, 2023.

(30) Foreign Application Priority Data
Sep. 28, 2022 (DE) 102022124933.6

(51) Int. Cl. H01J 37/16; H01J 37/09; H01J 37/14; H01J 37/147; H01J 37/244; H01J 37/28

(52) U.S. Cl. CPC H01J 37/16; H01J 37/09; H01J 37/14; H01J 37/1474; H01J 37/244; H01J 37/28; H01J 2237/0453; H01J 2237/04922; H01J 2237/1825

(57) ABSTRACT

A multi-beam particle microscope comprising a particle source configured to emit charged particles, and a multi-aperture arrangement configured to generate a first field of a multiplicity of charged first individual particle beams from the charged particles. A beam tube portion is arranged between the particle source and the multi-aperture arrangement. A condenser lens system with a magnetic lens can be arranged in the region of the beam tube portion. The beam tube portion comprises pure titanium or a titanium alloy, or the beam tube portion consists of pure titanium or a titanium alloy. The permeability coefficient of the pure titanium or of the titanium alloy is 1.0005 or less, such as 1.00005 or less. This can help make it possible to generate individual particle beams of better quality.

### CROSS-REFERENCE TO RELATED APPLICATIONS

The present application is a continuation of, and claims benefit under 35 USC 120 to, international application No. PCT/EP2023/025402, filed Sep. 21, 2023, which claims benefit under 35 USC 119 of German Application No. 10 2022 124 933.6, filed Sep. 28, 2022. The entire disclosure of each of these applications is incorporated by reference herein.

### FIELD

The disclosure relates to a multi-beam particle microscope which operates with a multiplicity of charged individual particle beams. The multi-beam particle microscope can include an improved beam tube.

### BACKGROUND

With the continuous development of ever smaller and ever more complex microstructures such as semiconductor components, it is generally desirable to further develop and optimize planar production techniques and inspection systems for producing and inspecting small dimensions of the microstructures. By way of example, the development and production of the semiconductor components involve monitoring of the design of test wafers, and the planar production techniques involve process optimization for reliable production with relatively high throughput. Moreover, there have been recent demands for an analysis of semiconductor wafers for reverse engineering and for a customized, individual configuration of semiconductor components. Therefore, it is desirable to provide an inspection system which can be used with relatively high throughput to examine the microstructures on wafers with relatively high accuracy.

Typical silicon wafers used in the production of semiconductor components have diameters of up to 300 millimeter (mm). Each wafer is subdivided into 30 to 60 repeating regions (“dies”) with a size of up to 800 square millimetres (mm²). A semiconductor apparatus comprises a plurality of semiconductor structures, which are produced in layers on a surface of the wafer by planar integration techniques. Semiconductor wafers typically have a plane surface on account of the production processes. The structure size of the integrated semiconductor structures in this case extends from a few μm to the critical dimensions (CD) of 5 nanometres (nm), and the structure sizes will become even smaller in the near future. In the future, structure sizes or critical dimensions (CD) are expected to be less than 3 nm, for example 2 nm, or even less than 1 nm. In the case of the aforementioned small structure sizes, defects of the size of the critical dimensions are desirably identified quickly over a very large area. For several applications, the specification for the accuracy of a measurement provided by inspection equipment is even higher, for example by a factor of two or one order of magnitude. By way of example, a width of a semiconductor feature is measured with an accuracy of below 1 nm, for example 0.3 nm or even less, and a relative position of semiconductor structures is determined with an overlay accuracy of below 1 nm, for example 0.3 nm or even less.

The MSEM, a multi-beam scanning electron microscope, is a relatively new development in the field of charged particle systems (“charged particle microscopes”, CPMs). By way of example, a multi-beam scanning electron microscope is disclosed in U.S. Pat. No. 7,244,949 B2 and in US 2019/0355544 A1. In the case of a multi-beam electron microscope or MSEM, a sample is irradiated simultaneously with a multiplicity of individual electron beams, which are arranged in a field or raster. By way of example, 4 to 10,000 individual electron beams can be provided as primary radiation, with each individual electron beam being separated from an adjacent individual electron beam by a pitch of 1 to 200 micrometres (μm). By way of example, an MSEM has approximately 100 separate individual electron beams (“beamlets”), which are arranged for example in a hexagonal raster, with the individual electron beams being separated by a pitch of approximately 10 μm. The multiplicity of charged individual particle beams (primary beams) are focused by a common objective lens onto a surface of a sample to be examined. By way of example, the sample can be a semiconductor wafer which is secured to a wafer holder mounted on a movable stage. During the illumination of the wafer surface with the charged primary individual particle beams, interaction products, for example secondary electrons or backscattered electrons, emanate from the surface of the wafer. Their start points correspond to those locations on the sample onto which the multiplicity of primary individual particle beams are focused in each case. The amount and the energy of the interaction products depend on the material composition and the topography of the wafer surface. The interaction products form multiple secondary individual particle beams (secondary beams), which are collected by the common objective lens and, by virtue of a projection imaging system of the multi-beam inspection system, are incident on a detector arranged in a detection plane. The detector comprises multiple detection regions, each of which comprises multiple detection pixels, and the detector captures an intensity distribution for each of the secondary individual particle beams. An image field of, for example, 100 μm×100 μm is obtained in the process.

A known multi-beam electron microscope comprises a sequence of electrostatic and magnetic elements. At least some of the electrostatic and magnetic elements are adjustable in order to adapt the focus position and the stigmation of the multiplicity of charged individual particle beams. Such a multi-beam system with charged particles moreover comprises at least one cross-over plane of the primary or the secondary charged individual particle beams. Such a system comprises detection systems to make the adjustment easier. Such a multi-beam particle microscope comprises at least one beam deflector (“deflection scanner”) for collective scanning of a region of the sample surface using the multiplicity of primary individual particle beams in order to obtain an image field of the sample surface. Further details regarding a multi-beam electron microscope and a method for operating same are described in the German patent application with the application number 102020206739.2, filed on 28 May 2020, and in the associated patent family documents, the disclosure of which is fully incorporated by reference in this patent application.

In order to obtain relatively high-resolution images and/or to be able to take relatively highly accurate measurements of structures using a multi-beam scanning electron microscope or more generally using a multi-beam particle microscope, the individual particle beams used for this can have the best possible particle-optical properties. It is known that properties or deviations of the generated individual particle beams from the ideal beam profile in the particle-optical beam path are therefore corrected, imaging errors are corrected by particle-optical lenses, and known disruptive influences, for example of mechanical, acoustic or magnetic type, on the individual particle beams are eliminated as far as possible. These measures also include the use or omission of materials with certain properties. Therefore, the particle beams are guided under vacuum or high vacuum in a so-called beam tube, which is known to be manufactured from a steel that can be worked very readily and moreover has virtually no magnetizability or has a very low permeability coefficient.

With continuously advancing improvement in the resolution of multi-beam particle microscopes, the demands placed on the quality of the individual particle beams generated are likewise increasing and there is therefore a constant desire for improvement.

U.S. Pat. No. 11,087,955 B2 discloses the use of a beam tube arrangement, which is in one piece and thus makes do without weld seams or solder points or solder seams, in the region of the beam splitter of multi-beam particle microscopes. In this case, the material for the beam tube arrangement in the region of the beam splitter may comprise copper or titanium. Titanium and titanium alloys can be difficult to work, although this is not important in U.S. Pat. No. 11,087,955 B2 owing to the one-piece nature of the beam tube arrangement.

US 2018/0166252 A1 discloses a single-beam electron microscope having a beam tube which comprises an inner and an outer beam tube cylinder. The inner beam tube cylinder may be produced from stainless steel or titanium. The use of an inner beam tube cylinder and an outer beam tube cylinder makes it possible to minimize effects on the electron beam inside the beam tube that are caused by magnetic field variations. Moreover, it is possible to produce each of the inner and the outer beam tube cylinder in one piece, with the result that the difficulties of working titanium in the production of the beam tube are not important.

US 2020/0013580 A1 discloses a single-beam electron microscope. The patent application discusses the suppression of parasitic thermal magnetic field noise using a double-walled beam tube. Titanium is mentioned alongside various other materials as a possible alternative for the inner beam tube. A one-piece configuration for the production of the beam tube is possible in principle in US 2020/0013580 A1 as well, and therefore difficulties in working titanium in the production of the beam tube are not important.

### SUMMARY

The present disclosure seeks to provide a multi-beam particle microscope which is improved overall. It can help provide improved resolution.

The object is achieved by the independent patent claim. Advantageous embodiments of the disclosure are evident from the dependent patent claims.

To precisely generate charged first individual particle beams via passage through a multi-aperture plate (filter plate), it is desirable for this multi-aperture plate to be illuminated or irradiated precisely. If the illumination is already not exact enough, it can become considerably more difficult or even impossible to ensure the desired particle-optical properties of the beams when the charged first individual particle beams are incident on a sample. Errors immediately during the formation of the first individual particle beams can fundamentally propagate with passage through the particle optical unit and, in general, can be corrected only with difficulty or even can no longer be corrected. These issues in the generation of the multiplicity of individual particle beams thus naturally do not exist in the case of individual beam systems.

For illumination purposes, collimation lens systems or more generally condenser lens systems with one or more particle lenses are used. In addition, deflectors are used to adjust or correct the direction of the illuminating beam as exactly as possible.

The lens fields created by the lenses should as far as possible not be distorted. This applies for example also to frequently used systems with a plurality of magnetic lenses. If further magnetic fields arise in the vicinity of magnetic lenses, they can distort the magnetic lens field and the quality of particle beams can deteriorate. That is why, in the case of certain known multi-beam particle microscopes, in the illumination region use is made of beam tubes of steel that have a low permeability coefficient, for example μ_{R}≤1.010 or μ_{R}≤1.005.

A specification that the materials used for the beam tube have a permeability coefficient μ_{R}≤1.005 is normally considered to be good enough. However, it has now surprisingly been found that the maximum permissible permeability coefficient can be exceeded, even in the case of materials that have a corresponding specification. The inventors have investigated possible causes of this more closely. Accordingly, one possible cause for the increased permeability coefficient is the occurrence of deformations. Stainless steels are defined as alloys of iron comprising at least 10.5% chromium and at most 1.2% carbon. Other alloy constituents, such as nickel, molybdenum, nitrogen and sulfur, can positively influence other properties. The main constituent of stainless steels, however, is iron. Pure iron is polymorphic, that is to say it can occur in different forms or modifications. Depending on the lattice structure, iron or iron alloys has or have different magnetic properties. Austenite refers to the face-centred cubic modification or phase of pure iron and its solid solution. Austenite is paramagnetic. Upon deformation, however, austenite can transform into martensite, which is ferromagnetic. The permeability coefficient therefore rises.

Corresponding deformations can occur as early as when the steel is machined. It has also been found that corresponding deformations can also arise in the form of damage that occurs during transit. It was therefore sought to develop corresponding ways of securing it during transit in order to reduce shocks and thus damaging deformations. Ultimately, however, this measure was not successful in reducing the permeability coefficient, or keeping it appropriately small, in a reliable manner in terms of the process.

Furthermore, the approach of converting the martensitic microstructure back to austenite by annealing the material was selected. This annealing led to a reduction in the permeability, or the permeability coefficient. This annealing, however, is not a standard process step, and it has surprisingly been shown that, although the permeability coefficient becomes smaller (that is to say better) shortly after the annealing operation, the permeability coefficient rises (that is to say becomes worse) over time.

As a result of these investigations, the inventors have realized that the permeability coefficient for the beam tube cannot be significantly improved, or cannot reliably be kept at the level striven for over a long period of time, with the known materials used for the beam tube.

Titanium is a light metal which has very good mechanical properties and a very low permeability coefficient. However, titanium or titanium alloys is or are difficult to work. It is generally difficult to weld titanium to titanium, since the material can become brittle. However, in the region of the illumination path or in the vicinity of the condenser lens system of multi-beam particle microscopes, it is not possible to avoid welding titanium to titanium, and a single-piece configuration (by contrast to U.S. Pat. No. 11,087,955 B2) is not an option here.

The length of a beam tube portion in the region of the condenser lens system is typically a few centimetres, for example between 10 centimetres (cm) and 15 cm or even more. At this length, it is generally desirable to correct shape and positional tolerances in order to generate the desired vacuum or high vacuum in the beam tube. It is therefore desirable to provide a diaphragm bellows or multiple diaphragm bellows of titanium or a titanium alloy. The prevalent opinion of corresponding manufacturers or those skilled in the art is therefore that titanium cannot be considered for use as beam tube portion in the illumination portion or at the level of the condenser lens system owing to the desired specifications.

However, the successful research of the inventors has shown that, by contrast to the previously established view, although it is difficult to work titanium in the way that is desired, it is still possible.

The disclosure generally involves two findings:
1. Although, in the case of a beam tube portion in the region of the condenser lens system or upstream of a multi-aperture arrangement, that is to say upstream of a first filter plate, the permeability coefficient of steel can be selected to be low enough (μ_{R}≤1.005) that de facto no issues should arise with the beam quality, the beam quality is surprisingly adversely affected.
2. By contrast to the view which is previously widespread, titanium can also actually be worked for the intended use.

In an aspect, the disclosure provides a multi-beam particle microscope comprising: a particle source, which is configured to emit charged particles; a multi-aperture arrangement, which is arranged in the beam path of the particles in such a way that at least some of the particles pass through openings in the multi-aperture arrangement in the form of individual particle beams, with the result that a first field of a multiplicity of charged first individual particle beams is generated; and a first particle optical unit which has a first particle-optical beam path and is configured to image the generated first individual particle beams onto an object plane such that the first individual particle beams are incident on an object at incidence locations, which form a second field; a detection unit with a multiplicity of detection regions, which form a third field; a second particle optical unit which has a second particle-optical beam path and is configured to image second individual particle beams, which emanate from the incidence locations in the second field, onto the third field of the detection regions of the detection system; an objective lens, through which both the first and the second individual particle beams pass; a beam splitter, which is arranged in the first particle-optical beam path between the multi-aperture arrangement and the objective lens and is arranged in the second particle-optical beam path between the objective lens and the detection unit; a controller, which is configured to control the multi-beam particle microscope or constituent parts of the multi-beam particle microscope; and an evacuable beam tube, in which the charged particles and/or the charged first individual particle beams and/or the charged second individual particle beams are guided at least in certain portions, wherein the evacuable beam tube has a beam tube portion which is arranged between the particle source and the multi-aperture arrangement, wherein the beam tube portion comprises pure titanium or a titanium alloy or wherein the beam tube portion consists of pure titanium or a titanium alloy, wherein, for the permeability coefficient μ_{R} of the pure titanium or of the titanium alloy, the following holds true: μ_{R}≤1.0005.

At least one particle source is provided, although it is also possible to provide multiple particle sources. The charged particles can be e.g. electrons, positrons, muons or ions or other charged particles. The charged particles can be electrons generated e.g. using a thermal field emission source (TFE). However, other particle sources can also be used. The individual field regions of the object (second field) that are assigned to each first individual particle beam are raster scanned, for example line by line or column by column. In this case, the individual field regions can be adjacent to one another or to cover the object or a part thereof in tessellated fashion. The individual field regions are substantially separate from one another, but they can also overlap one another in the marginal regions. In this way, it is possible to obtain an image of the object that is as complete and contiguous as possible. The individual field regions can have a rectangular or square form since this is the easiest to realize for the scanning process using particle radiation. The individual field regions can be arranged as rectangles in different lines one above another in such a way that the overall result is a hexagonal structure. It is advantageous if the number of particle beams is 3n (n−1)+1, where n is any natural number, in the hexagonal case. Other arrangements of the individual field regions, for example in a square or rectangular raster, are likewise possible.

The second individual particle beams can be backscattered electrons or else secondary electrons. In this case, for analysis purposes the low-energy secondary electrons can be used to generate the image. However, it is also possible for mirror ions/mirror electrons to be used as second individual particle beams, that is to say first individual particle beams undergoing reversal directly upstream of or at the object.

The multi-aperture arrangement comprises at least one multi-aperture plate which has a multiplicity of in particular round openings, through which the charged particle beam passes. It is also possible for the multi-aperture arrangement to have multiple multi-aperture plates. The multi-aperture arrangement may also have one or more multi-lens arrays. In addition or as an alternative, it is possible for the multi-aperture arrangement to have a multi-deflector array. It may comprise a multi-stigmator array. The multi-aperture arrangement may be provided in the form of an assembly, but this does not have to be the case. The multi-aperture arrangement may comprise or consist of what is referred to as the micro-optics of the multi-beam particle microscope.

The multi-beam particle microscope comprises an evacuable beam tube, in which the charged particles and/or the charged first individual particle beams and/or the charged second individual particle beams are guided at least in certain portions. This means that the beam tube can be subdividable into different portions. They may consist of the same material or different materials. It is for example possible for the beam tube to be interrupted by vacuum chambers, in which other components of the multi-beam particle microscope may be arranged. The vacuum or high vacuum that can be generated is for example less than 10⁻⁵ mbar, such as less than 10⁻⁷ mbar or less than 10⁻⁹ mbar.

According to the disclosure, the evacuable beam tube has a beam tube portion which is arranged between the particle source and the multi-aperture arrangement. This beam tube portion may for example extend completely from the particle source, or the chamber in which the latter is located, to the multi-aperture arrangement, or a further chamber in which the multi-aperture arrangement is located. In that case, this beam tube portion has the properties according to the disclosure. However, it is also possible, although in some cases not preferred, for the beam tube portion to be just one of multiple portions between the particle source and the multi-aperture arrangement. Then, in any case, it should be the longest beam tube portion between the particle source and the multi-aperture arrangement and/or the portion which is arranged closest to a condenser lens system of the multi-beam particle microscope.

According to the disclosure, the beam tube portion comprises pure titanium or a titanium alloy, or the beam tube portion consists of pure titanium or a titanium alloy, wherein for the permeability coefficient μ_{R} of the pure titanium or of the titanium alloy, the following holds true: μ_{R}≤1.0005. The desired permeability coefficient is thus at least one order of magnitude below the permeability coefficient that until now has been considered to be sufficient (μ_{R}≤1.005). For the permeability coefficient μ_{R} of the pure titanium or of the titanium alloy, the following can hold true: μ_{R}≤1.00005. This value is two orders of magnitude below the value that until now has been considered to be sufficient.

The expressions “pure titanium” and “titanium alloy” are used in the sense conventional in materials science within the meaning of this patent application. Titanium is characterized by grades 1 to 39 in accordance with the US American standard ASTM. Grades 1 to 4 denote pure titanium with different degrees of purity. Grade 5 titanium and above involve titanium alloys with different principal alloying elements.

According to an embodiment of the disclosure, the multi-beam particle microscope furthermore comprises a condenser lens system with at least one magnetic lens, which is configured to illuminate the multi-aperture arrangement with the charged particles, and which is arranged in the region of the beam tube portion. For example, the condenser lens system may be arranged around the beam tube portion; it is also possible to incorporate or integrate one or more of the magnetic lenses in the beam tube portion. It is decisive for the arrangement of the condenser lens system in the region of the beam tube portion that the lens field of the at least one magnetic lens is effective in the region of the beam tube portion. If the corresponding beam tube portion were then magnetized or to become magnetic, there would be a superposition with the magnetic lens field and thus distortion, which can also be asymmetrical in relation to the beam axis. As a result, the wavefronts of the charged particle beam would then no longer be aligned exactly plane or parallel in relation to the first multi-aperture plate of the multi-aperture arrangement, and the generated field of charged first individual particle beams would then comprise particle beams which are not oriented exactly parallel to one another. The telecentricity condition of the incidence on the multi-aperture arrangement when the individual particle beams are being formed would not be met to a great enough extent.

According to an embodiment of the disclosure, the multi-beam particle microscope furthermore comprises the following: an evacuable chamber, in which the multi-aperture arrangement is arranged, wherein the evacuable chamber has a cover which is connected to the beam tube portion, wherein the cover comprises pure titanium or a titanium alloy or wherein the cover consists of pure titanium or a titanium alloy, and wherein, for the permeability coefficient μ_{R} of the pure titanium or of the titanium alloy, the following holds true: μ_{R}≤1.0005, such as μ_{R}≤1.00005.

The cover of the evacuable chamber is thus on that side of the chamber that faces the particle source. The cover is therefore also located relatively close to a condenser lens system which is normally provided and has one or more magnetic lenses. A cover, even if it is only very slightly magnetic or magnetizable, would therefore likewise interact with the charged particle beam for example when passing through magnetic lens fields of the condenser lens system, and adversely affect the beam quality. Therefore, in principle the same considerations as for the beam tube portion also apply to the selection of material for the cover of the evacuable chamber in which the multi-aperture arrangement is arranged. The material used here can be pure titanium or a titanium alloy with a very low permeability coefficient.

The cover itself can be formed in one piece in order to avoid the formation of weld seams, which might cause additional distortions. The geometric shape of the cover is not decisive; it may for example have a substantially round or else polygonal, for example square, form.

The beam tube portion can be connected to the cover via electron beam welding, laser welding or plasma welding. However, other welding methods are also conceivable in theory.

According to an embodiment of the disclosure, the beam tube portion and/or the cover comprises one of the following materials or the beam tube portion and/or the cover consists of one of the following materials: grade 2 titanium, grade 5 titanium or grade 9 titanium. These designations correspond to the US American standard according to ASTM. Grade 2 titanium is technically pure titanium. Grade 5 titanium is a titanium alloy with aluminium and vanadium as principal alloying elements. By contrast to pure titanium, grade 5 titanium can be hardened. Its mechanical properties are even better. Grade 9 titanium is a titanium alloy with aluminium and vanadium as principal alloying elements. Grade 9 titanium is a compromise between the still relatively good welding and manufacturing properties of pure titanium, on the one hand, and the high strength of grade 5 titanium, on the other hand.

According to an embodiment of the disclosure, the beam tube portion and/or the cover comprise one of the following materials or consist of one of the following materials: 3.7035, 3.7164, 3.7165, 3.7195. These specified material numbers relate to the material numbers according to European standards. The materials mentioned have a permeability coefficient of 1.00005.

According to an embodiment of the disclosure, the beam tube portion and the cover are produced from the same material. The material is thus, for example, pure titanium of the same grade or the same titanium alloy of the same grade or materials with an identical material number according to European standards. This makes it easier to weld the beam tube portion to the cover, or makes this welding process possible at all.

According to an embodiment of the disclosure, the beam tube portion has a length of at least 10 cm along its axis. The beam tube portion may for example be 10, 11, 12, 13, 14 or 15 cm long, but it may also be longer still. The longer the beam tube portion is, the more susceptible it is in principle to deformations and the more easily the material or its permeability coefficient can be adversely affected by deformations, for example during production and/or transit. It is desirable for the material used to be pure titanium or a titanium alloy that has a considerably lower permeability coefficient than steel.

According to an embodiment of the disclosure, the beam tube portion has multiple parts which are connected to one another via electron beam welding, laser welding or plasma welding. Electron beam welding can be used. The use of multiple parts welded to one another makes it possible to compensate for shape and positional tolerances of the beam tube portion. The beam tube portion overall is then optionally slightly movable, for example when one or more diaphragm bellows are fitted. This is relevant in relation to the generation of the vacuum or high vacuum in the beam tube and thus also in the beam tube portion.

According to an embodiment of the disclosure, the beam tube portion comprises the following: a head piece close to the particle source, a tubular central piece, and an end piece close to the multi-aperture arrangement, wherein a diaphragm bellows with at least two diaphragms is provided between the head piece and the central piece, and/or wherein a diaphragm bellows with at least two diaphragms is provided between the central piece and the end piece.

The tubular central piece of the beam tube portion can be the longest piece or longest part of the beam tube portion. It may therefore have a geometrically particularly simple form, for example strictly tubular, or with a substantially circular cross section. The head piece close to the particle source may have a different shape than an ideal tube shape, for example a cross section of the head piece may be larger than that of the central piece. It is to be taken into consideration that the head piece should be designed in order to provide a sealing termination in the region of the particle source, this possibly involving a different shaping, for example when the particle source is also accommodated in a vacuum chamber. Similar considerations apply to the end piece close to the multi-aperture arrangement, it being possible for the end piece, for example, to be in the form of a flange. The precise shape of both the head piece and the end piece depends on the further part that is to be connected to or welded onto it, and the geometric shape of the head piece and of the end piece can be configured such that weld seams are prepared in optimum fashion.

The two diaphragm bellows can help ensure a slight movability between the pieces of the beam tube portion that it connects. They may be structurally identical, but do not have to be structurally identical. A diaphragm bellows may comprise two or more than two diaphragms. The two diaphragms of a bellows may be welded to one another, for example via electron beam welding, laser welding or plasma welding. Before the welding operation, the diaphragm or the diaphragms may be an integral constituent part of the head piece, of the central piece or of the end piece. As an alternative, they may likewise have been welded onto the head piece, the central piece or the end piece. According to an embodiment of the disclosure, for a material thickness d of a diaphragm, it holds true that: d≤0.50 mm, such as d≤0.20 mm or d≤0.15 mm; and/or a diaphragm bellows is formed by welding, such as electron beam welding, the two diaphragms to one another.

According to an embodiment of the disclosure, the beam tube portion and the cover are connected to one another via electron beam welding, laser welding or plasma welding. The end piece close to the multi-aperture arrangement can be connected to the cover via electron beam welding, laser welding or plasma welding.

According to an embodiment of the disclosure, the evacuable chamber in which the multi-aperture arrangement is arranged has a side wall, which comprises a material or consists of a material, for the permeability coefficient μ_{R} of which the following holds true: μ_{R}≤1.01. The permeability coefficient μ_{R} of this side wall is thus considerably higher than the permeability coefficient of the beam tube portion and for example also than the permeability coefficient of the cover. Specifically, it is no longer absolutely necessary to keep the permeability coefficient extremely low in the region of the side wall of the evacuable chamber. For the one part, a side wall of the evacuable chamber is farther away from the electron beam, or the multiplicity of individual particle beams, and for the other part, the side wall is farther away from the condenser lenses, or the lens fields of the magnetic lenses. Resulting distortion of the particle-optical beam path is thus considerably less likely. It is therefore possible to use materials that can be worked more easily—as was previously the case—for the side walls of the chamber.

According to an embodiment of the disclosure, the evacuable chamber has a side wall which comprises or consists of one of the following materials: 1.4435, 1.3952, 1.4429, 1.4369. The material numbers relate in turn to the European standard.

According to an embodiment of the disclosure, the cover is screwed to the side wall. This type of connection is relatively straightforward and is therefore possible. Titanium screws having a coating comprising tungsten disulfide can be used for the screwed connection. For example, for the coating, use can be made of specially modified tungsten disulfide in lamellar form, which is available under the trade name Dicronite®.

According to an embodiment of the disclosure, for the permeability coefficient of the beam tube portion, of the cover and of the side wall, the following holds true:
a) μ_{R-beam tube portion}<μ_{R-side wall}; and/or
b) μ_{R-cover}<μ_{R-side wall}; and/or

C) μ_{R-beam tube portion}=μ_{R-cover}.

The differences in magnitude in cases a) and b) may for example be a factor of 10 or a factor of 100.

According to an embodiment of the disclosure, the beam tube has a further beam tube portion, wherein the further beam tube portion consists of pure titanium or a titanium alloy, or wherein the beam tube portion consists of pure titanium or a titanium alloy, and wherein, for the permeability coefficient μ_{R} of the pure titanium or of the titanium alloy of the further beam tube portion, the following holds true: μ_{R}≤1.0005, such as μ_{R}≤ 1.00005. It is possible to likewise provide this further beam tube portion at a location of the beam tube where one or more further magnetic lenses are arranged. This may involve, for example, a magnetic lens of the field lens system or a magnetic lens of a projection lens system.

The various embodiments and aspects of the disclosure can be combined with one another in full or in part, provided that no technical contradictions arise as a result.

### BRIEF DESCRIPTION OF THE DRAWINGS

The disclosure will be understood even better with reference to the accompanying figures, in which:

FIG. 1: shows a schematic illustration of a multi-beam particle microscope (MSEM);

FIG. 2: schematically shows a multi-beam particle microscope with a beam tube;

FIG. 3: schematically shows the ideal incidence of an illuminating particle beam on a multi-aperture arrangement;

FIG. 4: schematically shows, in a manner not true to scale, a non-telecentric incidence of an illuminating particle beam on a multi-aperture arrangement; schematically shows a structure of a beam tube portion comprising pure FIG. 5: titanium or a titanium alloy with a low permeability coefficient; and

FIG. 6: schematically shows a structure of a beam tube portion and an evacuable chamber, which is connected to it and in which a multi-aperture arrangement is arranged.

### DETAILED DESCRIPTION

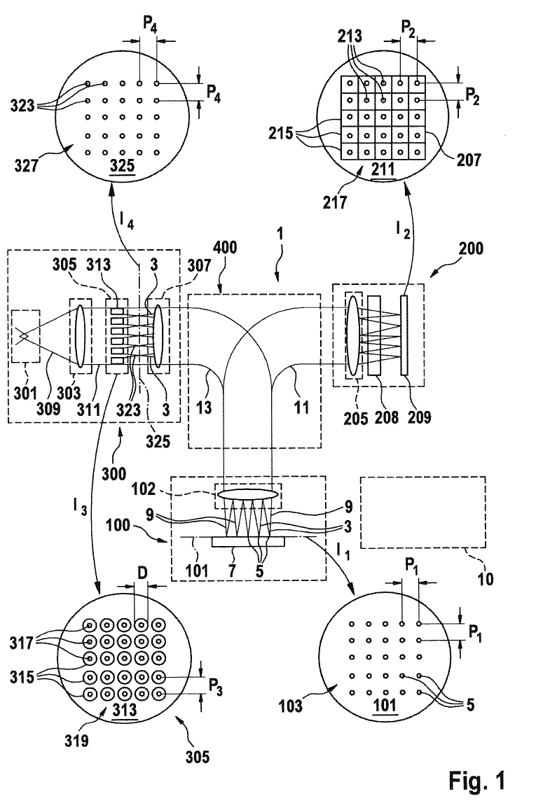

FIG. 1 is a schematic illustration of a particle beam system 1 in the form of a multi-beam particle microscope 1, which uses a multiplicity of particle beams. The particle beam system 1 generates a multiplicity of particle beams which are incident on an object to be examined in order to generate there interaction products, for example secondary electrons, which emanate from the object and are subsequently detected. The particle beam system 1 is of the scanning electron microscope (SEM) type, which uses multiple primary particle beams 3 which are incident on a surface of the object 7 at multiple locations 5 and there produce multiple electron beam spots, or spots, that are spatially separate from one another. The object 7 to be examined can be of any desired type, for example a semiconductor wafer or a biological sample, and may comprise an arrangement of miniaturized elements or the like. The surface of the object 7 is arranged in a first plane 101 (object plane) of an objective lens 102 of an objective lens system 100.

The enlarged detail 11 in FIG. 1 shows a plan view of the object plane 101 having a regular rectangular field 103 of incidence locations 5, which are formed in the first plane 101. In FIG. 1, there are 25 incidence locations, which form a 5×5 field 103. 25 incidence locations is a number chosen for reasons of simplified illustration. In practice, the number of beams, and hence the number of incidence locations, can be chosen to be significantly greater, such as, for example, 20×30, 100×100 and the like.

In the illustrated embodiment, the field 103 of incidence locations 5 is a substantially regular rectangular field having a constant pitch P1 between adjacent incidence locations. Exemplary values for the pitch P1 are 1 micrometre, 10 micrometres and 40 micrometres. However, it is also possible for the field 103 to have other symmetries, such as a hexagonal symmetry, for example.

A diameter of the beam spots formed in the first plane 101 can be small. Exemplary values of the diameter are 1 nanometre, 5 nanometres, 10 nanometres, 100 nanometres and 200 nanometres. The particle beams 3 for shaping the beam spots 5 are focused by the objective lens system 100.

The primary particles incident on the object generate interaction products, for example secondary electrons, backscattered electrons or primary particles which have undergone a reversal of movement for other reasons and which emanate from the surface of the object 7 or from the first plane 101. The interaction products emanating from the surface of the object 7 are shaped by the objective lens 102 to form secondary particle beams 9. The particle beam system 1 provides a particle beam path 11 for guiding the multiplicity of secondary particle beams 9 to a detector system 200. The detector system 200 comprises a particle optical unit with a projection lens 205 for directing the secondary particle beams 9 at a particle multi-detector 209.

The detail 12 in FIG. 1 shows a plan view of the plane 211, in which individual detection regions 215 of the particle multi-detector 209 on which the secondary particle beams 9 are incident at locations 213 are located. The incidence locations 213 lie in a field 217 with a regular pitch P2 from one another. Exemplary values for the pitch P2 are 10 micrometres, 100 micrometres and 200 micrometres.

The primary particle beams 3 are generated in a beam generating apparatus 300 comprising at least one particle source 301 (e.g. an electron source), at least one collimation lens 303, a multi-aperture arrangement 305 and a field lens 307. The particle source 301 generates a diverging particle beam 309, which is collimated or at least largely collimated by the collimation lens 303 in order to shape a beam 311 which illuminates the multi-aperture arrangement 305.

The detail 13 in FIG. 1 shows a plan view of the multi-aperture arrangement 305. The multi-aperture arrangement 305 comprises a multi-aperture plate 313, in which a plurality of openings or apertures 315 is formed. Midpoints 317 of the openings 315 are arranged in a field 319 that is imaged onto the field 103 formed by the beam spots 5 in the object plane 101. A pitch P3 between the midpoints 317 of the apertures 315 can have exemplary values of 5 micrometres, 100 micrometres and 200 micrometres. The diameters D of the apertures 315 are smaller than the pitch P3 between the midpoints of the apertures. Exemplary values for the diameters D are 0.2×P3, 0.4×P3 and 0.8×P3.

Particles of the illuminating particle beam 311 pass through the apertures 315 and form particle beams 3. Particles of the illuminating beam 311 which are incident on the plate 313 are absorbed by the latter and do not contribute to the formation of the particle beams 3.

On account of an applied electrostatic field, the multi-aperture arrangement 305 focuses each of the particle beams 3 in such a way that beam foci 323 are formed in a plane 325. Alternatively, the beam foci 323 can be virtual. A diameter of the beam foci 323 may be, for example, 10 nanometres, 100 nanometres and 1 micrometre.

The field lens 307 and the objective lens 102 provide a first imaging particle optical unit for imaging the plane 325, in which the beam foci 323 are formed, onto the first plane 101 such that a field 103 of incidence locations 5 or beam spots arises there. Should a surface of the object 7 be arranged in the first plane, the beam spots are correspondingly formed on the object surface.

The objective lens 102 and the projection lens arrangement 205 provide a second imaging particle optical unit for imaging the first plane 101 onto the detection plane 211. The objective lens 102 is thus a lens that is part of both the first and the second particle optical unit, while the field lens 307 belongs only to the first particle optical unit and the projection lens 205 belongs only to the second particle optical unit.

A beam splitter 400 is arranged in the beam path of the first particle optical unit between the multi-aperture arrangement 305 and the objective lens system 100. The beam splitter 400 is also part of the second optical unit in the beam path between the objective lens system 100 and the detector system 200.

Further information relating to such multi-beam particle beam systems and components used in them, such as particle sources, multi-aperture plate and lenses, can be obtained from the international patent applications WO 2005/024881 A2, WO 2007/028595 A2, WO 2007/028596 A1, WO 2011/124352 A1 and WO 2007/060017 A2 and the German patent applications DE 10 2013 016 113 A1 and DE 10 2013 014 976 A1, the disclosure of which is fully incorporated by reference in the present application.

The multi-beam particle microscope 1 furthermore comprises a computer system 10 designed both to control the individual particle-optical components of the multiple particle beam system and to evaluate and analyse the signals obtained by the multi-detector 209 or the detection unit 209. The computer system 10 can be constructed from multiple individual computers or components.

The multi-beam particle microscope 1 illustrated in FIG. 1 may comprise the beam tube according to the disclosure with the beam tube portion, which is arranged between the particle source 301 and the multi-aperture arrangement 305. In this respect, this beam tube portion may comprise pure titanium or a titanium alloy or the beam tube portion may consist of pure titanium or a titanium alloy, wherein, for the permeability coefficient μ_{R} of the pure titanium or of the titanium alloy, the following holds true: μ_{R}≤1.0005, such as μ_{R}≤1.00005.

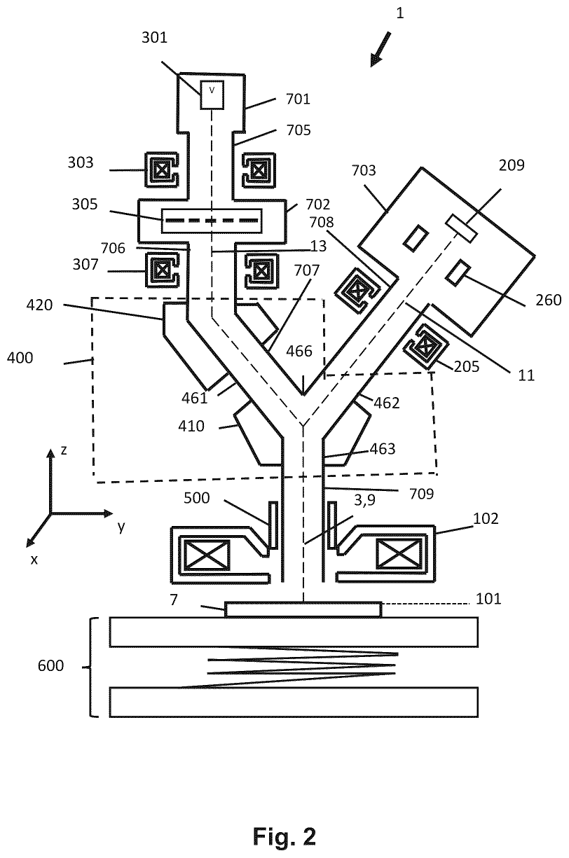

FIG. 2 schematically shows a multi-beam particle microscope 1 with a beam tube. The charged particles of the illuminating particle beam 311 (cf. FIG. 1) and also the charged first individual particle beams 3 and the charged second individual particle beams 9 are guided at least in certain portions in the beam tube. In the example shown, the beam tube is subdivided into a plurality of beam tube portions: The beam tube portion 705 is arranged between the particle source 301 and the multi-aperture arrangement 305, or associated vacuum chambers 701, 702 for the particle source and for the multi-aperture arrangement, respectively. The collimation lens system 303, or the condenser lens system 303, which in the example shown is schematically depicted by a schematically illustrated magnetic lens, is also arranged in the region of the beam tube portion 705. The collimation lens system 303, or the condenser lens system 303, may however of course also comprise more than one magnetic lens and/or one or more electrostatic lenses.

A further beam tube portion 706 is located downstream of the vacuum chamber 702 for the multi-aperture arrangement 305 in the direction of the particle-optical beam path. A field lens system 307 is illustrated schematically at the level of this beam tube portion 706. This field lens system comprises at least one magnetic lens, but it may also comprise multiple magnetic lenses and/or one or more electrostatic lenses.

The beam tube portion 707 is arranged downstream of the beam tube portion 706 in the direction of the particle-optical beam path. In the example shown, this beam tube portion 707 is a beam splitter portion in which the beam tube branches. The beam tube portion 707 comprises a first beam tube leg 461, a second beam tube leg 462 and a third beam tube leg 463. Only the first particle-optical beam path 13 extends through the first beam tube leg 461 and only the second particle-optical beam path 11 extends through the second beam tube leg 462. By contrast, both the first particle-optical beam path 13 and the second particle-optical beam path 11 extend through the third beam tube leg 463. The beam tube portion 707 is substantially y-shaped and has a branching point 466. A further beam tube portion 709, which extends to the magnetic objective lens 102, adjoins the beam tube portion 707 in the direction of the first particle-optical beam path 13. A further beam tube portion 708, which is arranged in the region of a projection lens system 205 illustrated only schematically in FIG. 2, adjoins the beam tube portion 707 in relation to the second particle-optical beam path 11. A further vacuum chamber 703, inside which the detection system 209 is arranged, is arranged adjoining the beam tube portion 708.

Provided inside the beam tube with its beam tube portions 705, 706, 707, 708 and 709 and in the vacuum chambers 701, 702, 703, is a vacuum which typically has a pressure of less than 10⁻⁵ mbar, such as less than 10⁻⁷ mbar, for example less than 10⁻⁹ mbar.

In terms of magnetic properties of the beam tube and possibly resulting distortions during the formation or shaping of the individual particle beams 3, the beam tube portion 705, or its position between the particle source 301 and the multi-aperture arrangement 305, can be particularly relevant or particularly sensitive. In the beam tube portion 705, the illuminating particle beam 311 in the first place provides the conditions for providing the multiplicity of individual particle beams 3. It is therefore desirable for the condenser lens system 303 to illuminate the multi-aperture arrangement 305 with charged particles extremely precisely. It can be desirable, for example, for a telecentricity condition of the illuminating beam 311 when it is incident on the first multi-aperture plate 313 of the multi-aperture arrangement 305 to be exactly met. The wavefronts of the illuminating beam 311 when it is incident on this first multi-aperture plate 313 or filter plate 313 is desirably exactly parallel to the surface of the multi-aperture plate 313 or filter plate 313. Otherwise, the first individual particle beams 3 are already slightly distorted when they are produced, this normally not being able to be corrected again as they progress along the first particle-optical beam path 13. Moreover, the total beam current of the illuminating particle beam 311 is very great and the beam diameter is likewise very great (compared in each case with properties of an individual particle beam). The magnetic field of the condenser lens system 303 is likewise relatively strong. All these factors promote possible interactions between the illuminating particle beam 311 and an only slightly magnetic or magnetizable beam tube. These interactions should therefore be eliminated as far as possible. Therefore, the choice of the corresponding material for the beam tube portion 705 is of decisive importance. The permeability coefficient μ_{R} can be relatively small, for example one or two orders of magnitude smaller than it is for steel, this being the case for the materials mentioned, pure titanium and titanium alloys. In that case, the permeability coefficient may be μ_{R}≤1.00005.

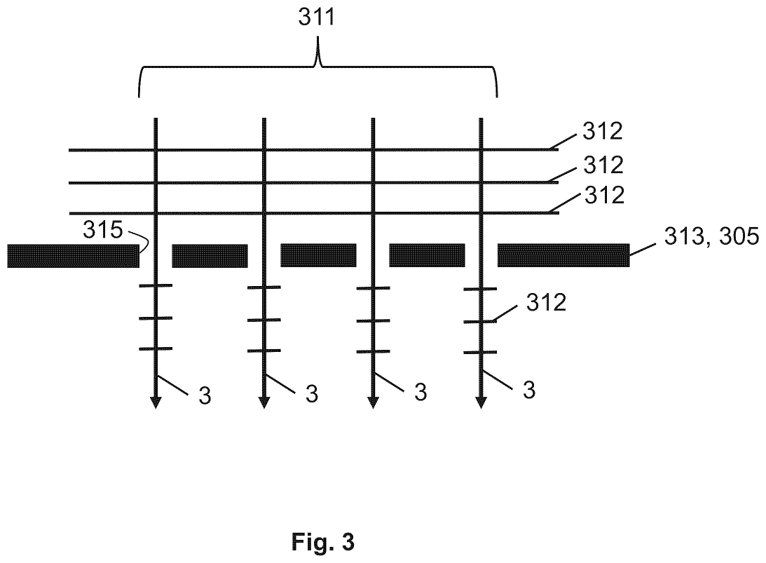

FIG. 3 schematically shows the ideal incidence of an illuminating particle beam 311 on a multi-aperture arrangement 305 or a multi-aperture plate 313 with a multiplicity of openings 315, which are circular in the example shown. In this case, the multi-aperture arrangement 305 is illustrated only in simplified fashion and may for example comprise, in addition to the first multi-aperture plate 313 (filter plate), one or more further multi-aperture plates, a multi-lens array and one or more multi-deflector arrays. In particular, the so-called micro-optics of the multi-beam particle microscope 1 may be a constituent part of the multi-aperture arrangement 305.

The illuminating particle beam 311, for example an electron beam, is formed as a collimated particle beam 311 by a condenser lens system 303 (not illustrated in FIG. 3). Its wavefronts 312 are straight and exactly parallel to one another. Their orientation is likewise parallel to the first multi-aperture plate 313. The illuminating particle beam 311 is thus incident completely telecentrically on the first multi-aperture plate 313 and the multiplicity of first individual particle beams 3 formed by passage through the multi-aperture plate 313 are exactly parallel to one another and also the wavefronts of the individual particle beams 3 are exactly parallel to the surface of the multi-aperture plate 313. The initial optical properties of the individual particle beams 3 are thus as ideal as possible.

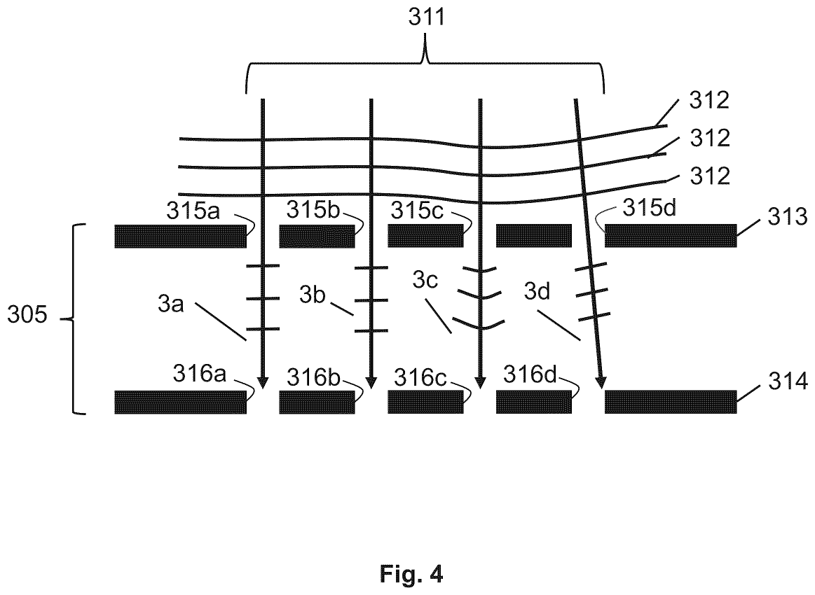

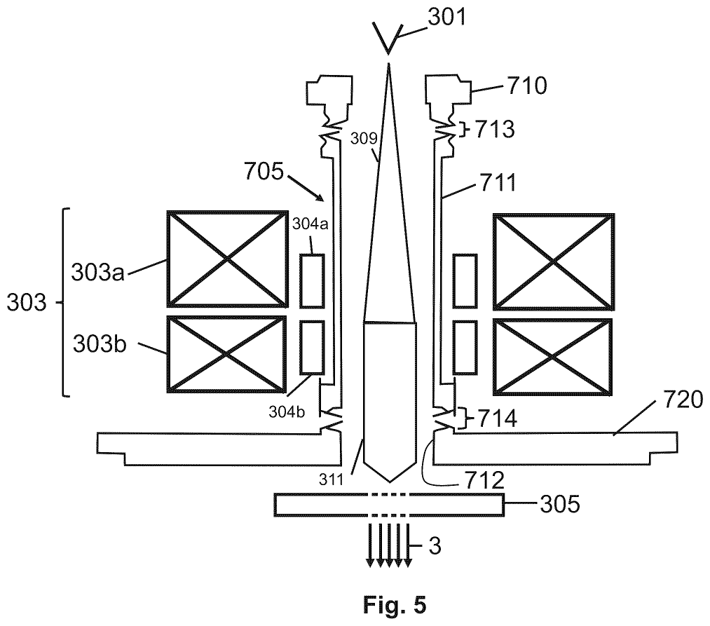

FIG. 4 by contrast schematically shows, in a manner not true to scale, the non-telecentric incidence of an illuminating particle beam 311 on a multi-aperture arrangement 305. The wavefronts 312 of the illuminating particle beam 311 are no longer straight and also no longer parallel to the first multi-aperture plate 313. Instead, the wavefront 312 is curved in the region above the openings 315c and 315d in the multi-aperture plate 313; by contrast and in comparison, the wavefronts extend ideally and parallel to the first multi-aperture plate 313 above the openings 315a and 315b.

Directly below the openings 315a, 315b, 315c and 315d, the effect caused by the non-telecentric incidence of the illuminating particle beam 311 on the multi-aperture plate 313 is still relatively small. However, the distortion becomes then greater in the course of the particle-optical beam path 13. Illustrated by way of example is the situation upon incidence on the second multi-aperture plate 314, which is likewise part of the multi-aperture arrangement 305: The particle beams 3a and 3b are undistorted, and their wavefronts 312 are parallel to the surface of the second multi-aperture plate 314. These particle beams 3a and 3b pass through the associated openings 316a and 316b in the second multi-aperture plate 314 ideally and without issues. It is different in the case of the first particle beams 3c and 3d. The particle beam 3c is slightly divergent and the wavefront 312c is curved. As a result, the particle beam 3c does not pass through the opening 316c ideally, and the particle beam 3c does not meet the telecentricity condition. Although the particle beam 3d has straight wavefronts 312d, its beam axis is inclined in relation to the optimum optical axis, and the beam propagates slightly obliquely and thus also does not pass through the opening 316d optimally. As a result, the beam quality continues to deteriorate in the course of the particle-optical beam path 13. This deterioration is admittedly small and manifests for example in a slight increase in noise. However, this distortion in the individual beam generation is to be avoided in order to further improve the resolution of the multi-beam particle microscope 1 overall. With ever increasing demands on the resolution, a slight increase in noise also makes itself noticeable, or has a disadvantageous effect. The distortion, which is illustrated schematically and in greatly exaggerated fashion in FIG. 4, can be avoided according to the disclosure by the choice of material and a corresponding structure of the beam tube portion 705.

FIG. 5 schematically shows a structure of a beam tube portion 705 comprising pure titanium or a titanium alloy with a low permeability coefficient μ_{R}. In the example shown, for the permeability coefficient μ_{R}, the following holds true: μ_{R}≤1.00005. All of the regions illustrated in a hatch pattern in FIG. 5 are made from pure titanium or a titanium alloy for which μ_{R}≤1.00005. The beam tube portion 705 made from or with titanium extends substantially from the particle source 301 to the multi-aperture opening 305, or from the vacuum chamber 701 for the particle source 301 (not illustrated in FIG. 5) to the vacuum chamber 702, only the cover 720 of which is illustrated in FIG. 5. A condenser lens system 303, which has two magnetic lenses 303a and 303b in the example shown, is illustrated in the region of the beam tube portion 705. The respective refractive power of the magnetic lenses 303a and 303b can be set for example using the controller 10 of the multi-beam particle microscope 1. For fine adjustment of the illuminating particle beam 311, deflectors 304a and 304b are provided, which may for example be octupole electrodes. The beam tube portion 705 comprises multiple parts or pieces in the example shown. The beam tube portion 705 has a head piece 710 close to the particle source, a tubular central piece 711, and an end piece 712 close to the multi-aperture arrangement. A diaphragm bellows 713, which has two diaphragms and is indicated in the drawing as thin lines projecting into the beam tube portion 705, is provided between the head piece 710 and the central piece 711. In the example shown, these two diaphragms are connected via electron beam welding, a possible alternative being laser beam welding or plasma welding.

In addition, a further diaphragm bellows 714 with two diaphragms is provided between the central piece 711 and the end piece 712. Here, too, the two diaphragms of the diaphragm bellows 714 protrude into the beam tube 705 as thin diaphragms. The diaphragms are each very thin. Their material thickness may be for example only fractions of a millimetre, for example 0.1 mm, 0.15 mm or 0.2 mm or 0.5 mm. The overall extent of the diaphragm bellows and thus the height of the diaphragm bellows in the z direction, or in the direction of the particle-optical beam path, may likewise be less than 1 mm, for example 0.8 mm or 0.6 mm. Owing to these small dimensions and the particular desired properties for welding pure titanium or titanium alloys, welding a corresponding connection was previously generally considered not to be possible. However, it was then found that welding is actually possible, in particular electron beam welding.

In the example shown, the end piece 712 is welded to the cover of an evacuable chamber 702, in which the multi-aperture arrangement 305 is arranged. In the example shown, it is likewise possible to use electron beam welding; alternatively laser welding or plasma welding is a connection option. The corresponding weld seams between the end piece 712 and the cover 720 are not illustrated in FIG. 5. For corresponding preparation of the weld seam, however, it is possible for example for the end piece 712 to have an overall form similar to a flange.

In the example shown, the different parts both of the beam tube portion 705 and of the cover 720 are produced from the same material. This material may, for example, be grade 2 titanium, grade 5 titanium or grade 9 titanium, these expressions being used in accordance with the US American standard ASTM. Corresponding materials in accordance with European standards are materials having the material numbers 3.7035, 3.7164, 3.7165 and 3.7195. The length of the beam tube portion 705 along its axis in this case is at least 10 cm, for example 10 cm or 11 cm or 12 cm or 15 cm or more still. Owing to this length, it is especially relevant to compensate shape and positional tolerances of the beam tube portion 705. It is therefore particularly advantageous to provide the two diaphragm bellows 713 and 714 in the way presented above.

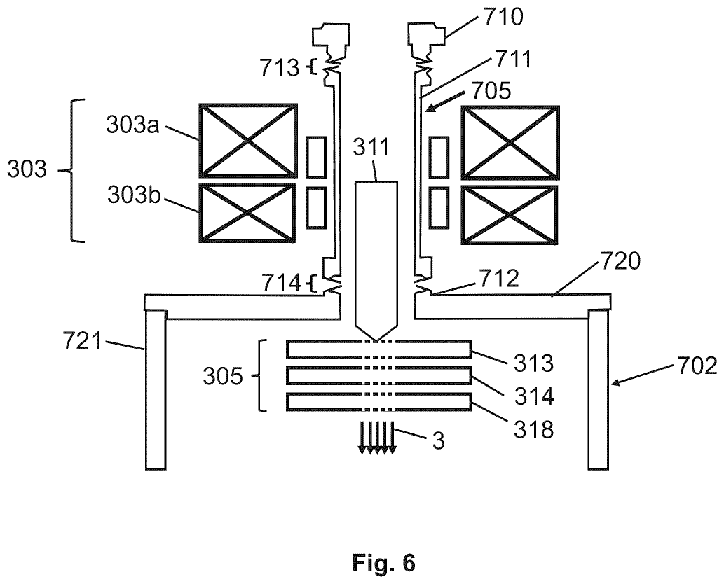

FIG. 6 schematically shows further details of a multi-beam particle microscope 1, in particular in terms of the schematic structure of the beam tube portion 705 and an evacuable chamber 702 which is connected to it and in which a multi-aperture arrangement 305 is arranged. Large parts in FIG. 6 correspond to FIG. 5, and therefore only the differences, or further details illustrated only in FIG. 6, will be discussed below.

In addition to the cover 720 of the vacuum chamber 702, FIG. 6 also illustrates a side wall 721. The cover 720 is substantially round with a central opening for the illuminating particle beam 311. Correspondingly, the side wall 721 runs circularly around the periphery in the example shown. The side wall 721 is produced from a different material than the cover 720: The side wall 721 comprises a material or consists of a material, for the permeability coefficient μ_{R} of which only the following holds true: μ_{R}≤1.01, in particular 1.005≤μ_{R}≤1.010. This condition may already be met for steel, which can be worked readily. The permeability coefficient of the side wall is thus typically higher than the permeability coefficient of the cover, for example at least by a factor of 10 or at least a factor of 100. By way of example, the side wall 721 of the evacuable chamber 702 comprises a material or consists of a material with the following material numbers: 1.4435, 1.3952, 1.4429, 1.4369. The side wall 721 is considerably farther away both from the particle beams 3 and from the condenser lens system 303. Any distortions owing to too high permeability coefficients of the side wall 721 thus affect the beam quality to a considerably lesser extent. In the example shown, the cover 720 is screwed to the side wall 721. In this case, for example, use can be made of screws of titanium, which can have a coating comprising tungsten disulfide. For example, for the coating, use can be made of specially modified tungsten disulfide in lamellar form, which is available under the trade name Dicronite®.

The described features make it possible to significantly improve the beam quality of the individual particle beams 3 and it is possible to achieve a higher resolution of the multi-beam particle microscope 1.

### LIST OF REFERENCE SIGNS

1 Multi-beam particle microscope
3 Primary particle beams (individual particle beams)
5 Beam spots, incidence locations
7 Object, sample
9 Secondary particle beams
10 Computer system, controller
11 Secondary particle beam path
13 Primary particle beam path
101 Object plane
102 Objective lens
103 Field
200 Detector system
205 Projection lens
207 Scintillator plate
208 Deflector for adjustment purposes
209 Detection system, particle multi-detector, detection unit
211 Detection plane
213 Incidence locations, beam spot of the secondary particles or of the associated photon beam
215 Detection region
217 Field
300 Beam generating apparatus
301 Particle source
303 Collimation lens system, condenser lens system
304 Deflector
305 Multi-aperture arrangement
307 Field lens system
309 Diverging particle beam
311 Illuminating particle beam
312 Wavefront
313 Multi-aperture plate
314 Multi-aperture plate
315 Openings in the multi-aperture plate
316 Openings in the multi-aperture plate
317 Midpoints of the openings
318 Multi-aperture plate
319 Field
323 Beam foci
325 Intermediate image plane
400 Beam splitter
410 Magnetic sector
420 Magnetic sector
466 Branching point
461 Beam tube leg
462 Beam tube leg
463 Beam tube leg
701 Vacuum chamber for particle source
702 Vacuum chamber for multi-aperture opening
703 Vacuum chamber for detection system
705 Beam tube portion (illumination portion)
706 Beam tube portion (field lens portion)
707 Beam tube portion (beam splitting portion)
708 Beam tube portion (projection portion)
709 Beam tube portion (objective lens portion)
710 Head piece
711 Central piece
712 End piece
5 713 Diaphragm bellows
714 Diaphragm bellows
720 Cover
721 Side wall

What is claimed is:

1. A multi-beam particle microscope, comprising:
a particle source configured to emit charged particles;
a multi-aperture arrangement configured so at least some of the charged particles pass through openings in the multi-aperture arrangement in the form of multiple individual particle beams to generate a first field of a multiplicity of charged first individual particle beams;
a first particle optical unit having a first particle-optical beam path, the first particle optical unit configured to image the charged first individual particle beams onto an object plane so that the charged first individual particle beams are incident on an object in the object plane at incidence locations to form a second field;
a detection unit comprising a multiplicity of detection regions configured to form a third field;
a second particle optical unit having a second particle-optical beam path, the second particle optical unit configured to image charged second individual particle beams emanating from the incidence locations in the second field onto the third field of the detection regions of the detection system;
an objective lens through which both the charged first and second individual particle beams pass;
a beam splitter in the first particle-optical beam path between the multi-aperture arrangement and the objective lens, the beam splitter in the second particle-optical beam path between the objective lens and the detection unit;
a controller configured to control at least some constituent parts of the multi-beam particle microscope; and
an evacuable beam tube in which the charged particles and/or the charged first individual particle beams and/or the charged second individual particle beams are guided at least in certain portions,
wherein:
the evacuable beam tube comprises a beam tube portion between the particle source and the multi-aperture arrangement;
the beam tube portion comprises a material, or the beam tube consists of the material;
the material is selected from the group consisting of a titanium or a titanium alloy; and
the material has a permeability coefficient of 1.0005 or less.

2. The multi-beam particle microscope of claim 1, wherein the permeability coefficient of material is 1.00005 or less.

3. The multi-beam particle microscope of claim 1, further comprising a condenser lens system comprising a magnetic lens, wherein the condenser lens system is configured to illuminate the multi-aperture arrangement with the charged particles, and the condenser lens is in a region of the beam tube portion.

4. The multi-beam particle microscope of claim 1, further comprising an evacuable chamber, wherein:
the multi-aperture arrangement is in the evacuable chamber;
the evacuable chamber comprises a cover connected to the beam tube portion;
the cover comprises a cover material, or the cover consists of the cover material;
the cover material is selected from the group consisting of pure titanium or a titanium alloy; and
the cover material has a permeability of the cover is 1.0005 or less.

5. The multi-beam particle microscope of claim 4, wherein the beam tube portion and/or the cover comprise or consist of one of the following materials: grade 2 titanium, grade 5 titanium or grade 9 titanium.

6. The multi-beam particle microscope of claim 4, wherein the beam tube portion and/or the cover comprise or consist of one of the following materials: 3.7035 according to the European standard, 3.7164 according to the European standard, 3.7165 according to the European standard, or 3.7195 according to the European standard.

7. The multi-beam particle microscope of claim 4, wherein the beam tube portion and the cover comprise the same material.

8. The multi-beam particle microscope of claim 4, wherein the beam tube portion and the cover are electron beam welded together, laser welded together, or plasma welded together.

9. The multi-beam particle microscope of claim 4, wherein the evacuable chamber comprises a side wall having a permeability coefficient of 1.01 or less.

10. The multi-beam particle microscope of claim 4, wherein the evacuable chamber comprises a side wall comprising or consisting of one of the following materials: 1.4435 according to the European standard, 1.3952 according to the European standard, 1.4429 according to the European standard, or 1.4369 according to the European standard.

11. The multi-beam particle microscope of claim 4, wherein the evacuable chamber comprises a side wall, and the cover is screwed to the side wall.

12. The multi-beam particle microscope of claim 4, wherein:
the evacuable chamber comprises a side wall having a permeability;
a permeability of the beam tube portion is less than the permeability of a side wall;
the permeability of the cover is less than the permeability of the side wall; and
the permeability of the beam tube portion is less than the permeability of the cover.

13. The multi-beam particle microscope of claim 1, wherein the beam tube portion is at least 10 centimetres long along its axis.

14. The multi-beam particle microscope of claim 1, wherein the beam tube portion comprises multiple parts welded together.

15. The multi-beam particle microscope of claim 1, wherein the beam tube portion comprises multiple parts electron beam welded together, laser welded together, or plasma welded together.

16. The multi-beam particle microscope of claim 15, wherein:
the beam tube portion comprises a head piece, a tubular central piece, and an end piece;
the head piece is closer to the particle source than is either the tubular central piece or the end piece;
the end piece is closer to the multi-aperture arrangement than is either the head piece or the tubular central piece; and
the multi-beam particle microscope further comprises:
a first diaphragm bellows comprising two diaphragms between the head piece and the central piece; and
a second diaphragm bellows comprising two diaphragms between the central piece and the end piece.

17. The multi-beam particle microscope of claim 16, wherein at least one of the following holds:
a material thickness of at least one of the diaphragms is 0.50 millimetre or less; and
the two diaphragms of at least one of the first and second diaphragm bellows are welded together.

18. The multi-beam particle microscope of claim 1, wherein:
the beam tube comprises a further beam tube portion;
the further beam tube portion comprises a further beam tube portion material, or the the further beam tube portion consists of the further beam tube portion material;
the further beam tube portion material is selected from the group consisting of a pure titanium and a titanium alloy; and
a permeability coefficient of the further beam tube portion material is 1.0005 or less.

19. The multi-beam particle microscope of claim 1, wherein the material is selected from the group consisting of grade 2 titanium, grade 5 titanium, and grade 9 titanium.

20. The multi-beam particle microscope of claim 1, wherein the material is selected from the group consisting of 3.7035 according to the European standard, 3.7164 according to the European standard, 3.7165 according to the European standard, and 3.7195 according to the European standard.

21. A multi-beam particle microscope, comprising:
a particle source configured to emit charged particles;
a multi-aperture arrangement configured so at least some of the charged particles pass through openings in the multi-aperture arrangement;
a first particle optical unit configured to image the charged first individual particle beams onto an object plane;
a detection unit;
a second particle optical unit configured to image charged second individual particle beams emanating from the object plane onto the detection unit; and
a beam tube in which the charged particles and/or the charged first individual particle beams and/or the charged second individual particle beams are guided at least in certain portions,
wherein at least a portion of the tube between the particle source and the multi-aperture arrangement comprises or consists of a material selected from the group consisting of a titanium or a titanium alloy, and the material has a permeability coefficient of 1.0005 or less.

22. A multi-beam particle microscope, comprising:
a particle source configured to emit charged particles;
a multi-aperture arrangement configured so at least some of the charged particles pass through openings in the multi-aperture arrangement in the form of multiple individual particle beams to generate a first field of a multiplicity of charged first individual particle beams;
a first particle optical unit having a first particle-optical beam path, the first particle optical unit configured to image the charged first individual particle beams onto an object plane so that the charged first individual particle beams are incident on an object in the object plane at incidence locations to form a second field;
a detection unit comprising a multiplicity of detection regions configured to form a third field;
a second particle optical unit having a second particle-optical beam path, the second particle optical unit configured to image charged second individual particle beams emanating from the incidence locations in the second field onto the third field of the detection regions of the detection system;
an objective lens through which both the charged first and second individual particle beams pass;
a beam splitter in the first particle-optical beam path between the multi-aperture arrangement and the objective lens, the beam splitter in the second particle-optical beam path between the objective lens and the detection unit; and
a beam tube in which the charged particles and/or the charged first individual particle beams and/or the charged second individual particle beams are guided at least in certain portions,
wherein a portion of the beam tube between the particle source and the multi-aperture arrangement comprises or consists of a material selected from the group consisting of a titanium or a titanium alloy, and the material has a permeability coefficient of 1.0005 or less.
